(19) United States
(12) Patent Application Publication
(10) Pub. No.: US 2025/0096117 A1
(43) Pub. Date: Mar. 20, 2025

(54) INTEGRATED CIRCUITS INCLUDING STACKED THIN FILM INDUCTORS AND METHODS OF FABRICATION

(71) Applicant: QUALCOMM Incorporated, San Diego, CA (US)

(72) Inventors: Anshih Tseng, Fremont, CA (US); Peng Zou, Camas, WA (US); Joseph Dibene, Watsonville, CA (US); Gerard Williams, Newport Coast, CA (US)

(21) Appl. No.: 18/469,908

(22) Filed: Sep. 19, 2023

(51) Int. Cl. H01L 23/522; H01F 41/14; H01F 41/34; H01L 23/00

(52) U.S. Cl. CPC H01L 23/5227; H01F 41/14; H01F 41/34; H01L 24/02; H01L 24/05; H01L 24/06; H01L 24/13; H01L 24/14; H01L 2224/02313; H01L 2224/02331; H01L 2224/0401; H01L 2224/05008; H01L 2224/05022; H01L 2224/05073; H01L 2224/05562; H01L 2224/05569; H01L 2224/05573; H01L 2224/06102; H01L 2224/13006; H01L 2224/13007; H01L 2224/13021; H01L 2224/1403

(57) ABSTRACT

Passive components located outside the IC increase the area of the package and are connected to the circuits inside the IC by long electrical paths that may have high resistance as well as parasitic inductance and capacitance. An IC includes interconnect layers on a surface of a substrate comprising circuits, and the interconnect layers include stacked thin-film inductors formed in interconnect layers to provide noise protection for input signals provided to circuits in the IC while reducing an area of an IC package. The stacked thin-film inductors include a first thin-film inductor stacked between a second thin-film inductor and the surface of the substrate in a direction orthogonal to the surface of the substrate. The thin-film inductors can be formed of layers of magnetic material around a linear interconnect. The interconnect layers may be formed in a back end of line process on one surface of a substrate.

### BACKGROUND

### I. Field of the Disclosure

The technology of the disclosure relates generally to signal quality in integrated circuits and, more particularly, to passive components integrated into an IC to improve signal quality.

### II. Background

Integrated circuits (ICs) may have a wide variety of functions provided by transistor based digital logic and analog circuits. The digital logic circuits as well as the analog circuits strongly rely on the existence of a known difference in voltage between a ground voltage (V_{SS}) and a power supply voltage (V_{DD}) provided to the IC. A surge or spike in current or voltage in the power supply can cause fluctuations in a power distribution network that result in functional errors and even damage to circuits. Similarly, fluctuations in input signals provided to the IC can change the relative voltage between signals and the power supply voltage. Voltage fluctuations, also referred to as noise, can be reduced by passive components, including capacitors and inductors. To provide noise protection to ICs mounted on printed circuit boards (PCBs) or substrates, inductors and capacitors are mounted on the PCB around the IC to provide noise protection. However, the passive components are far away from the circuits they are protecting, which reduces their effectiveness. Increasing the sizes of the passive components can make them more effective, but also causes them to occupy more area on the PCB. The long electrical paths from the off-chip passive components to the circuits they protect also have high resistance and are susceptible to parasitic capacitance and inductance, which adds to signal delay.

### SUMMARY

Aspects disclosed in the detailed description include integrated circuits (ICs) including stacked thin-film inductors. Related methods of fabricating an IC including stacked thin-film inductors are also disclosed. IC packages include passive components to reduce noise in input signals provided to circuits on an IC die or substrate. Such components located outside the IC die increase the package size and are coupled to the circuits by long electrical paths that may have high resistance, reducing their effectiveness. An exemplary IC includes interconnect layers disposed on a surface of a substrate comprising circuits with stacked thin-film inductors in the interconnect layers on the substrate to provide improved noise protection for input signals and to reduce area of an IC package. The stacked thin-film inductors include a first thin-film inductor in a first interconnect layer, where the first thin-film inductor is between a second thin-film inductor in a second interconnect layer and the surface of the substrate in a direction orthogonal to the surface of the substrate. In some examples, the first and second thin-film inductors are formed within the interconnect layers as magnetic material disposed around a linear interconnect that carries an input signal. The interconnect layers may be formed, for example, in a back end of line process on one surface of the substrate of the IC die.

In this regard, in one exemplary aspect, an IC is disclosed. The IC includes a substrate comprising a surface and a circuit coupled to a first pad contact on the surface, a first interconnect layer disposed on the surface of the substrate and including a first thin-film inductor including a first linear interconnect of a first length extending in a first direction, and a second interconnect layer disposed on the first interconnect layer and including a second thin-film inductor including a second linear interconnect of a second length extending in the first direction. The first linear interconnect having the first length is between the second linear interconnect having the second length and the surface of the substrate in a second direction orthogonal to the surface of the substrate.

In another exemplary aspect, a method in an IC is disclosed. The method includes forming a substrate including a surface and a circuit coupled to a first pad contact on the surface, forming a first interconnect layer on the surface of the substrate and including a first thin-film inductor including a first linear interconnect of a first length extending in a first direction, and forming a second interconnect layer disposed on the first interconnect layer and including a second thin-film inductor including a second linear interconnect of a second length extending in the first direction. The first linear interconnect having the first length is between the second linear interconnect having the second length and the surface of the substrate in a second direction orthogonal to the surface of the substrate.

### BRIEF DESCRIPTION OF THE DRAWINGS

FIG. 1 is an isometric view of a conventional integrated circuit (IC) package including an IC mounted on a printed circuit board (PCB) including passive components disposed on the PCB outside the IC to provide noise protection for signals and power provided to the IC;

FIG. 2A is a cross-sectional side view in a first direction of thin-film inductors that are stacked in layers on a surface of a substrate of an exemplary IC and configured to provide inductance between pad contacts on the substrate surface and bump contacts to provide on-chip noise and surge protection in the IC;

FIG. 2B is a cross-sectional view of the IC in FIG. 2A through interconnect layers disposed on the surface of the substrate to show vias in interconnect layers coupled by linear interconnects, and magnetic layers disposed around the linear interconnects to form the thin-film inductors;

FIG. 2C is a cross-sectional side view of the thin-film inductors formed in the interconnect layers on the IC in FIGS. 2A and 2B, showing structural aspects including the magnetic layers providing inductance in the linear interconnects;

FIG. 2D is a close-up cross-sectional side view in the first direction of an example of stacked horizontal thin-film inductors coupled in parallel in the layers on the surface of the exemplary IC in FIGS. 2A-2C;

FIG. 3 is an isometric view of a second example of stacked horizontal thin-film inductors on a substrate surface of the IC in FIG. 2A in which the thin-film inductors are provided to protect electrically separate signals;

FIG. 4 is an isometric view of a third example of stacked horizontal thin-film inductors coupled in series to protect a same signal on the substrate surface of the IC in FIG. 2A;

FIG. 5 is a flowchart illustrating an exemplary method of fabricating the stacked horizontal thin-film inductors on the substrate surface of the IC in FIGS. 2A-2D;

FIGS. 6A-6C are a flowchart describing stages of fabrication of the IC illustrated in FIGS. 7A-1 to 7P-2, including one example of vertically stacked horizontal thin-film inductors on a surface of a substrate of the IC to provide noise and surge protection;

FIGS. 7A-1 to 7P-2 are illustrations of cross-sectional side views in two directions of the IC in FIGS. 2A-2D in stages of fabrication as described in FIGS. 6A-6C;

FIG. 8 is a block diagram of an exemplary wireless communication device that includes an IC including stacked thin-film inductors on a surface of a substrate to provide noise and surge protection as shown in FIGS. 2A-2D, 3, and 4 and fabricated according to, but not limited to, any of the exemplary methods in FIGS. 5 and 6A-6C; and

FIG. 9 is a block diagram of an exemplary processor-based system that can include ICs including stacked thin-film inductors on a surface of a substrate to provide noise and surge protection as shown in FIGS. 2A-2D, 3, and 4 and fabricated according to, but not limited to, any of the exemplary methods in FIGS. 5 and 6A-6C.

### DETAILED DESCRIPTION

Several exemplary aspects of the present disclosure are described in reference to the drawing figures. The word “exemplary” is used herein to mean “serving as an example, instance, or illustration.” Any aspect described herein as “exemplary” is not necessarily to be construed as preferred or advantageous over other aspects.

Aspects disclosed in the detailed description include integrated circuits (ICs) including stacked thin-film inductors. Related methods of fabricating an IC including stacked thin-film inductors are also disclosed. IC packages include passive components to reduce noise in input signals provided to circuits on an IC die or substrate. Such components located outside the IC die increase the package size and are coupled to the circuits by long electrical paths that may have high resistance, reducing their effectiveness. An exemplary IC includes interconnect layers disposed on a surface of a substrate comprising circuits with stacked thin-film inductors in the interconnect layers on the substrate to provide improved noise protection for input signals and to reduce area of an IC package. The stacked thin-film inductors include a first thin-film inductor in a first interconnect layer, where the first thin-film inductor is between a second thin-film inductor in a second interconnect layer and the surface of the substrate in a direction orthogonal to the surface of the substrate. In some examples, the first and second thin-film inductors are formed within the interconnect layers as magnetic material disposed around a linear interconnect that carries an input signal. The interconnect layers may be formed, for example, in a back end of line process on one surface of the substrate of the IC die.

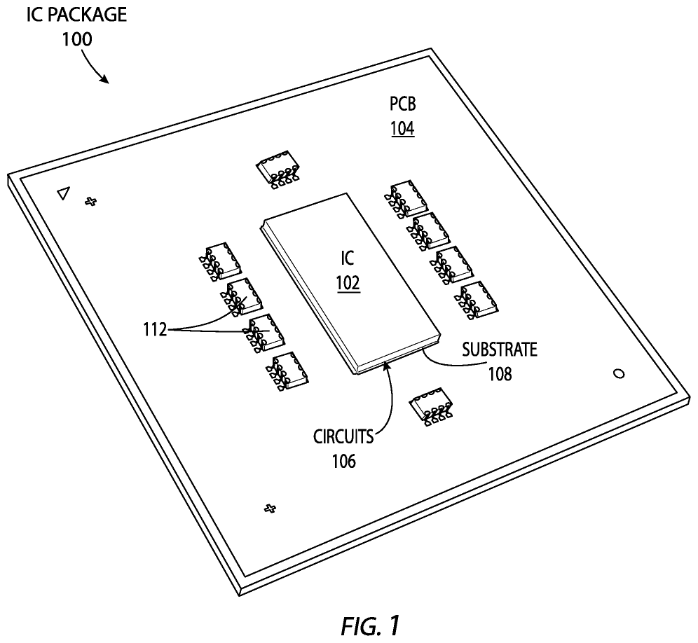

FIG. 1 is an isometric view of a conventional integrated circuit (IC) package 100 including an IC 102 mounted on a printed circuit board (PCB) 104. The IC 102 includes circuits 106 formed on a die or substrate 108. Signals are provided to the circuits 106 through passive components 112 (e.g., capacitors and inductors). The passive components 112 protect the circuits 106 from noise (e.g., spikes or surges in current or voltage) in the signals. The passive components 112 may include inductors that reduce the severity of surges in current, which is particularly important in power supply signals for powering an IC or power supply signals provided to an analog power management IC. Due to the volume occupied by three-dimensional coil inductors and the area occupied by two-dimensional spiral inductors, including them in an IC can cause a significant increase in both the die size and associated costs. For this reason, the passive components 112 are mounted on the PCB 104 outside the IC 102, which increases the size of the PCB 104 of the IC package 100. In addition, the interconnect length from the passive components 112 to the circuits 106 is very large relative to on-die interconnect lengths, causing a high DC resistance and high propagation delay, which may have adverse effects on circuit performance. For example, a high resistance from the passive components 112 to the IC 102 can reduce a Q-factor of the circuits 106.

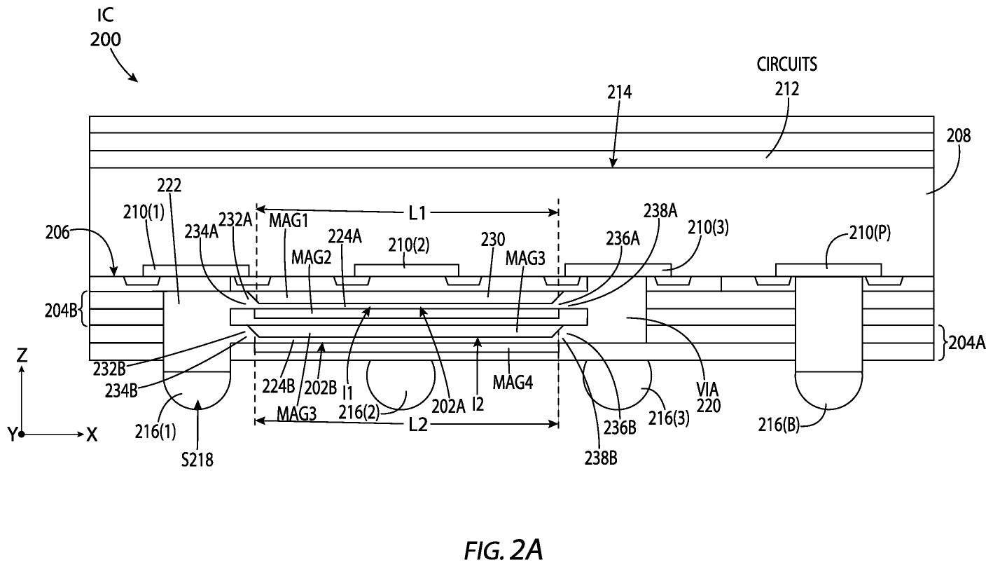

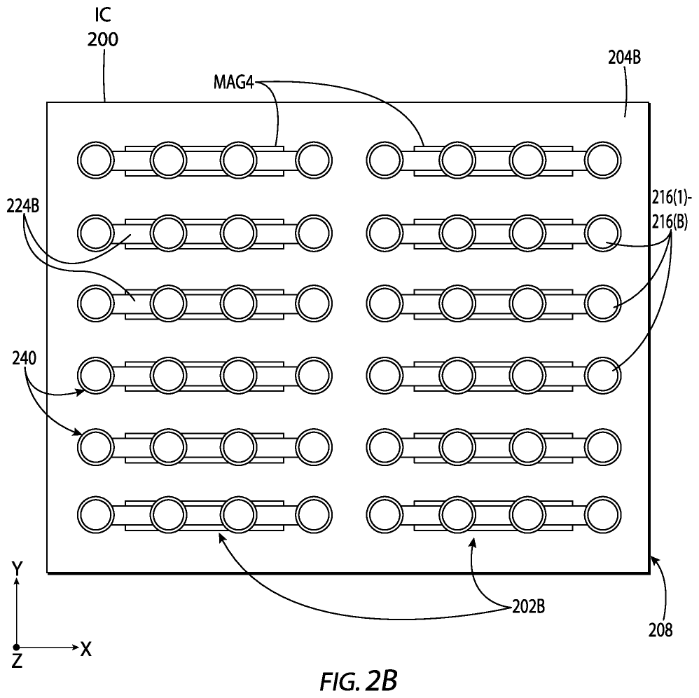

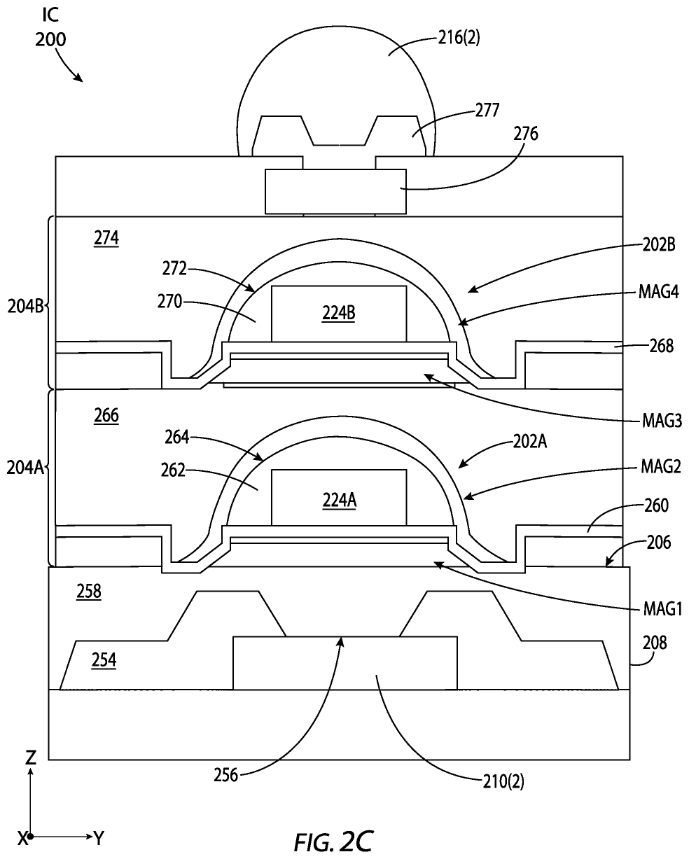

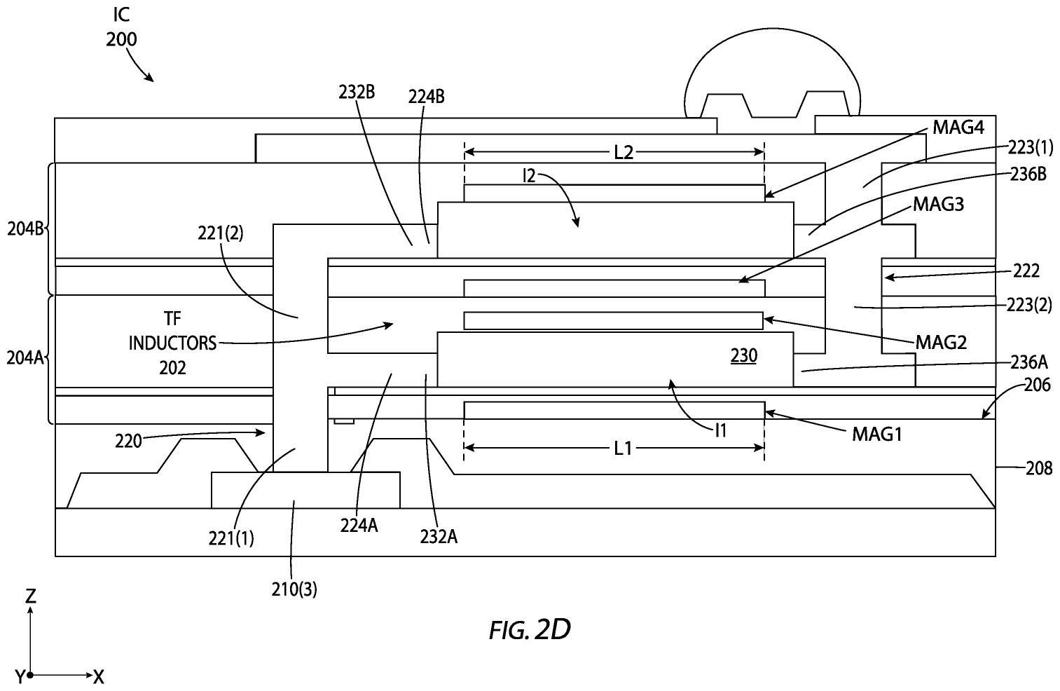

FIG. 2A is a cross-sectional side view in a first direction (Y-axis direction) of an exemplary IC 200 including stacked thin-film inductors 202A, 202B (referred to collectively as “TF inductors 202”) that are formed in interconnect layers 204A, 204B, respectively, on a surface 206 of a substrate 208. The IC 200 includes pad contacts 210(1)-210(P) (where P may be any integer) on the surface 206 coupled to circuits 212 on the substrate 208. The circuits 212 may be formed, for example, on a second surface 214 of the substrate 208. Bump contacts 216(1)-216(B) (where B may be any integer) are provided on the interconnect layers 204A, 204B to couple the circuits 212 to an external circuit (not shown).

As shown in the example in FIG. 2A, the interconnect layers 204A, 204B include an interconnect circuit providing an electrical path from the bump contact 216(1) to the pad contact 210(3). The bump contact 216(1) may be employed to physically and electrically couple the IC 200 to a PCB (not shown) and receive a signal S218. The signal S218 may be a power supply signal that powers the circuits 212 or is regulated by the circuits 212. Alternatively, signal S218 may be a logic signal for data or control in the circuits 212. Rather than having external passive components, as illustrated in FIG. 1, coupled to the bump contact 216(1) to provide noise and surge protection in the signal S218, the TF inductors 202 are provided in the interconnect layers 204A, 204B for this purpose.

This example includes a first vertical interconnect access (via) 220 that is coupled to the pad contact 210(3) and extends through the interconnect layers 204A, 204B in a second direction (Z-axis direction) orthogonal to the surface 206. The example in FIG. 2A also includes a second via 222 coupled to the bump contact 216(1) and extending in the second direction through the interconnect layers 204A, 204B. As shown in the cross-sectional view in FIG. 2A, the first thin-film inductor 202A includes a first linear interconnect 224A extending in a third direction (X-axis direction) in the first interconnect layer 204A to couple the first via 220 to the second via 222. The second thin-film inductor 202B includes a second linear interconnect 224B extending in the third direction in the second interconnect layer 204B and also couples the first via 220 and the second via 222. The first linear interconnect 224A and the second linear interconnect 224B are formed of an electrically conductive material such as a metal, e.g., copper, as an example. The first and second linear interconnects 224A, 224B each include at least one linear portion of the conductive material disposed in a straight line (e.g., along an axis) in the corresponding one of the interconnect layers 204A, 204B. Together, the first via 220, the first and second linear interconnects 224A, 224B, and the second via 222 provide an electrical path coupling the pad contact 210(3) to the bump contact 216(1).

In addition to the first linear interconnect 224A, the first thin-film inductor 202A includes a first magnetic layer MAG1 disposed on a first side (e.g., top side in the Z-axis direction in FIG. 2A) of the first linear interconnect 224A and a second magnetic layer MAG2 disposed on a second, opposite side (e.g., bottom side) of the first linear interconnect 224A. The first magnetic layer MAG1 and the second magnetic layer MAG2 are each formed of a magnetic material 230 that extends a first length L1 in the third direction. The first magnetic layer MAG1 and the second magnetic layer MAG2 may be alternatively referred to herein as the first layer of magnetic material MAG1 and the second layer of magnetic material MAG2. The magnetic material 230 extending the first length L1 produces an inductance I1 through the first linear interconnect 224A. A first end 232A of the first linear interconnect 224A coupled to the first via 220 provides a first terminal 234A of the first thin-film inductor 202A and a second end 236A of the first linear interconnect 224A coupled to the second via 222 provides a second terminal 238A of the first thin-film inductor 202A. In this regard, a portion of the first linear interconnect 224A between the first magnetic layer MAG1 and the second magnetic layer MAG2 having the length L1 comprises a portion of the first thin-film inductor 202A. The ends 232A and 236A at each end of the length L1 provide the terminals 234A and 238A.

Similarly, in addition to the second linear interconnect 224B, the second thin-film inductor 202B includes a first magnetic layer MAG3 disposed on a first side (e.g., top side in the Z-axis direction in FIG. 2A) of the second linear interconnect 224B and a second magnetic layer MAG4 disposed on a second, opposite side (e.g., bottom side) of the second linear interconnect 224B. The first magnetic layer MAG3 and the second magnetic layer MAG4 of the second thin-film inductor 202B are each formed of the magnetic material 230 extending a second length L2 in the third direction. Based on the magnetic material 230 and the second length L2 of the first and second magnetic layers MAG3, MAG4, an inductance 12 is produced in the second linear interconnect 224B. The second length L2 may be the same length or a different from the first length L1, depending on a desired relationship of the inductances I1 and I2. A first end 232B of the second linear interconnect 224B coupled to the first via 220 provides a first terminal 234B of the second thin-film inductor 202B and a second end 236B of the second linear interconnect 224B coupled to the second via 222 provides a second terminal 238B of the second thin-film inductor 202B. In this regard, the first thin-film inductor 202A is coupled in parallel with the second thin-film inductor 202B. The portion of the first linear interconnect 224A having the first length L1 in the first thin-film inductor 202A may be between (e.g., directly between) a portion of the second linear interconnect 224B having the length L2 and the surface 206 of the substrate 208.

The TF inductors 202 may provide protection of the signal S218 in a manner similar to the inductors 114 in FIG. 1. Even though the TF inductors 202 may have different inductances 11, 12 than the inductors 114, the TF inductors 202 can provide a similar or improved level of noise and/or surge protection due to their close proximity and short interconnect distance to the circuits 212. Additionally, forming the TF inductors 202 on the surface 206 of the substrate 208 saves area of a package (e.g., of a PCB) compared to IC packages including external passive components.

FIG. 2B is a cross-sectional view of the IC 200 in FIG. 2A through the interconnect layers 204B disposed on the substrate 208 to show the second magnetic layers MAG4 disposed around the linear interconnects 224B to form thin-film inductors 202B as shown in FIG. 2A. FIG. 2B also shows the bump contacts 216(1)-216(B) disposed on top of the interconnect layer 204B. Some of the bump contacts 216(1)-216(B) are coupled to vias 240, which may include the vias 220 and 222 shown in FIG. 2A and the vias 240 are coupled to each other by the linear interconnects 224B. Additional aspects of a structure of the thin-film inductors 202A and 202B is shown more clearly in FIG. 2C.

FIG. 2C is a side view in the third direction (X-axis direction) of a cross-section (in the Y-axis and Z-axis directions) through the IC 200 including the thin-film inductors 202A, 202B in the interconnect layers 204A, 204B in FIG. 2A. FIG. 2C illustrates features of the thin-film inductors 202A, 202B formed on the surface 206 of the substrate 208. In this example, the first thin-film inductor 202A is formed directly between (e.g., along a straight line between) the second thin-film inductor 202B and the surface 206 in the Z-axis direction (orthogonal to the surface 206).

Beginning at the surface 206, the IC 200 includes one of the pad contacts 210(1)-210(P), such as the pad contact 210(2) in FIG. 2A. An insulation material 254 disposed thereon to define a contact location 256 where a conductive material may be deposited to form a via coupled to the pad contact 210(2), but such via may not be provided here to avoid interfering with the first thin-film inductor 202A. A first inter-layer material 258 is disposed on the pad contact 210(2) and on the surface 206 of the substrate 208.

The first and second interconnect layers 204A, 204B are formed on the first inter-layer material 258. Additional details of the fabrication of the features of the first and second interconnect layers 204A, 204B shown in FIG. 2C are provided below with reference to FIGS. 7A-1 to 7P-2.

The first interconnect layer 204A comprises the first magnetic layer MAG1 formed on the first inter-layer material 258. The first magnetic layer MAG1 may be a planar layer. A first dielectric layer 260 is disposed over the first magnetic layer MAG1 to isolate the first linear interconnect 224A from the first magnetic layer MAG1. The cross-section in FIG. 2C provides an end view of the first linear interconnect 224A disposed on the first dielectric layer 260. In this view, it can be clearly seen that the linear interconnect 224A is the only linear interconnect between the second layer of magnetic material MAG2 and the first layer of magnetic material MAG1.

Thus, the first magnetic layer MAG1 is on a first side of the first linear interconnect 224A (e.g., in the Z-axis direction) and the first dielectric layer 260 is between the first linear interconnect 224A and the first magnetic layer MAG1. A second dielectric layer 262 is disposed around the remaining sides (e.g., left side, right side, and top side in FIG. 2C) of the first linear interconnect 224A. The second dielectric layer 262 appears in a dome shape in the cross-section in FIG. 2C and extends in the third direction (X-axis), such that an exterior surface 264 of the second dielectric layer 262 is semi-cylindrical. Consequently, when the second magnetic layer MAG2 of the first thin-film inductor 202A is deposited or otherwise formed on the second dielectric layer 262, the second magnetic layer MAG2 also takes on a semi-cylindrical shape. The second dielectric layer 262 is disposed in the semi-cylindrical shape between the first linear interconnect 224A and the second magnetic layer MAG2. Where the second magnetic layer MAG2 extends down the sides (left and right) of the second dielectric layer 262 (in the Z-axis direction in FIG. 2C), the second magnetic layer MAG2 is isolated from the first magnetic layer MAG1 by the first dielectric layer 260. A second inter-layer material 266 is disposed on the second magnetic layer MAG2 to complete the first interconnect layer 204A. The first interconnect layer 204A is not limited to the layers shown in FIG. 2C and additional layers may be employed even if not described herein.

With continuing reference to FIG. 2C, the steps in forming the first interconnect layer 204A may be repeated to form the second interconnect layer 204B. The second interconnect layer 204B comprises the first magnetic layer MAG3 of the second thin-film inductor 202B, which is formed on the second inter-layer material 266. The first magnetic layer MAG3 may be a planar layer. A third dielectric layer 268 is disposed over the first magnetic layer MAG3 to isolate the second linear interconnect 224B from the first magnetic layer MAG3. The cross-section in FIG. 2C also provides an end view of the second linear interconnect 224B disposed on the third dielectric layer 268. Thus, the first magnetic layer MAG3 is on a first side of the second linear interconnect 224B (e.g., in the Z-axis direction) between the second linear interconnect 224B and the second magnetic layer MAG2 of the first thin-film inductor 202A. A fourth dielectric layer 270 is disposed around the remaining sides of the second linear interconnect 224B. The fourth dielectric layer 270 is dome shaped in the cross-section in FIG. 2C and extends in the third direction (X-axis), such that an exterior surface 272 of the fourth dielectric layer 270 is semi-cylindrical. The second magnetic layer MAG4 of the second thin-film inductor 202B formed on the fourth dielectric layer 270 also takes on a semi-cylindrical shape (e.g., similar to a cylinder split along its axis). The second magnetic layer MAG4 extends down the sides of the fourth dielectric layer 270 but is isolated from the first magnetic layer MAG3 by the third dielectric layer 268. A third inter-layer material 274 is disposed on the second magnetic layer MAG4 to complete the second interconnect layer 204B. In this example, a metal layer 276 is formed on the second interconnect layer 204B, then an under bump metal 277 and a bump contact 216(2), for example, may be formed on the metal layer 276. The second interconnect layer 204B is also not limited to the layers shown in FIG. 2C and additional layers may be employed.

FIG. 2D is a close-up cross-sectional side view in the Y-axis direction of the IC 200 including the TF inductors 202 coupled in parallel in the interconnect layers 204A, 204B on the surface 206 of the substrate 208. Features of FIG. 2D that are also shown in FIGS. 2A-2C may be labeled alike. FIG. 2D shows that the magnetic layers MAG1 and MAG2 extend a first length L1 in the X-axis direction on opposite sides of the first linear interconnect 224A and the magnetic layers MAG3 and MAG4 extend a second length L2 in the X-axis direction on opposite sides of the second linear interconnect 224B. The inductances I1 and I2 may be determined by magnetic materials 230 and by the lengths L1 and L2, which are the same in this example but are not so limited. FIG. 2D shows the via 220 comprises a first via 221(1) extending in the Z-axis direction and coupled to the first pad contact 210(3) and to the first linear interconnect 224A. The via 220 includes a second via 221(2) coupled to the first via 220(1), extending in the Z-axis direction, and coupling the first linear interconnect 224A to the second linear interconnect 224B. The via 220 is coupled to the first ends 232A, 232B of the respective first and second linear interconnects 224A, 224B.

The via 222 comprises a first via 223(1) extending in the Z-axis direction to couple the bump contact 216(1) to the second end 236B of the second linear interconnect 224B and a second via 223(2) coupling the second end 236B of the second linear interconnect 224B to the second end 236A of the first linear interconnect 224A.

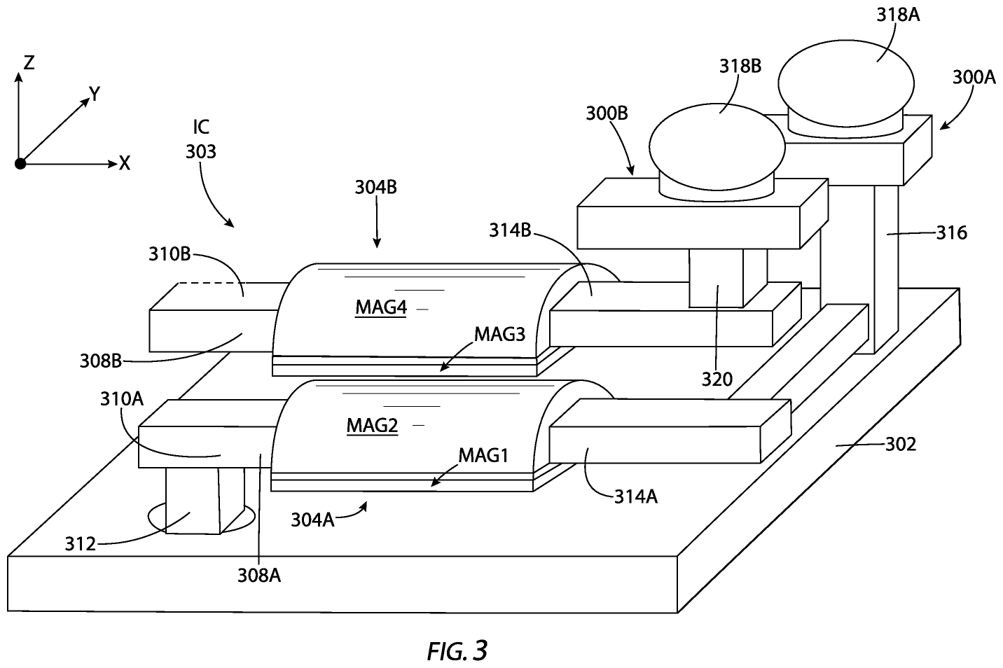

FIG. 3 is an isometric view of an example of electrically separate interconnect circuits 300A and 300B that may be disposed on a substrate 302 of an IC 303 and include a second thin-film inductor 304B stacked on a first thin-film inductor 304A. The first thin-film inductor 304A includes a first linear interconnect 308A disposed between a first magnetic layer MAG1 and a second magnetic layer MAG2. The second thin-film inductor 304B includes a second linear interconnect 308B disposed between a first magnetic layer MAG3 and a second magnetic layer MAG4. The first linear interconnect 308A is between the second linear interconnect 308B and the substrate 302.

In this example, a first end 310A of the first linear interconnect 308A provides a first terminal of the first thin-film inductor 304A and is coupled to a via 312. The via 312 may be further coupled to a pad contact or to another metal layer (not shown). A second end (terminal) 314A of the first linear interconnect 308A is coupled to a second via 316 which is further coupled to a bump contact 318A. A first end 310B of the second thin-film inductor 304B may be coupled to another pad contact (not shown) and is not coupled to the first terminal 310A of the first thin-film inductor 304A, and a second end 314B of the second thin-film inductor 304B is not coupled to the second end 314A of the first thin-film inductor 304A. The second end 314B of the second thin-film inductor 304B is coupled to a second bump contact 318B through a via 320. Thus, the first thin-film inductor 304A providing an inductance in the first interconnect circuit 300A is electrically isolated from the second thin-film inductor 304B in the second interconnect circuit 300B.

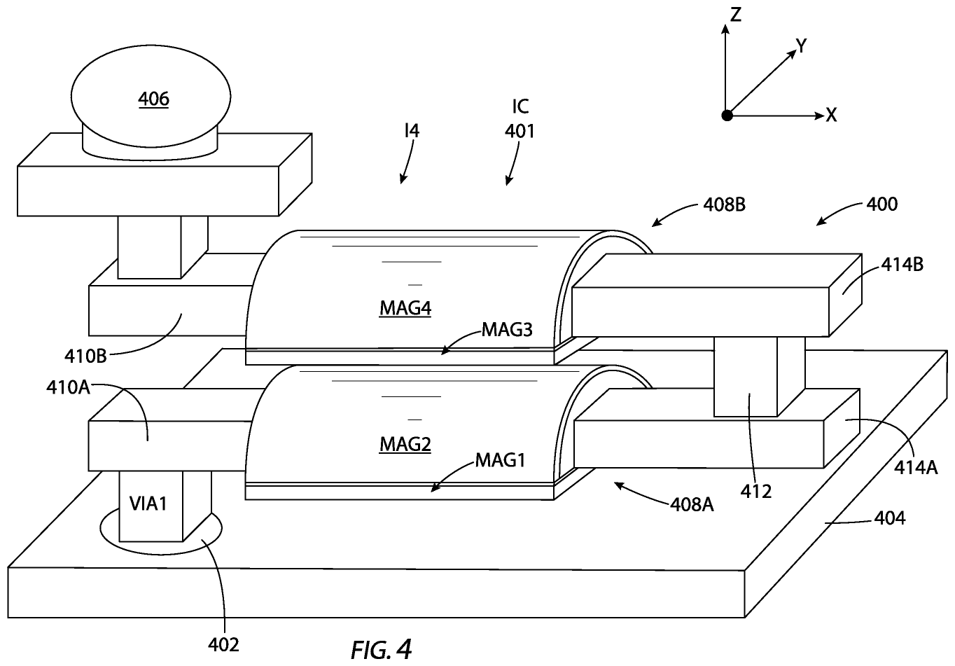

FIG. 4 is an isometric view of an example of an interconnect circuit 400 that may be formed in interconnect layers of an IC 401 to couple a pad contact 402 on a substrate 404 to a bump contact 406. The interconnect circuit 400 includes a second thin-film inductor 408B stacked on a first thin-film inductor 408A. The first and second thin-film inductors 408A, 408B correspond to the thin-film inductors 202A, 202B in FIGS. 2A-2D including magnetic layers MAG1, MAG2, MAG3, and MAG4. A first terminal 410A of the first thin-film inductor 408A is coupled to the pad contact 402 and a first terminal 410B of the second thin-film inductor 408B is coupled to the bump contact 406. A via 412 is coupled to second terminals 414A, 414B of the first and second thin-film inductors 408A, 408B. Thus, in contrast to the examples in FIGS. 2A-2D in which the stacked first and second thin-film inductors 202A, 202B are coupled in parallel and the example in FIG. 3 in which the stacked first and second thin-film inductors 304A, 304B are electrically isolated from each other, the stacked first and second thin-film inductors 408A, 408B are coupled in series to provide a total inductance 14 to protect a signal received at the bump contact 406.

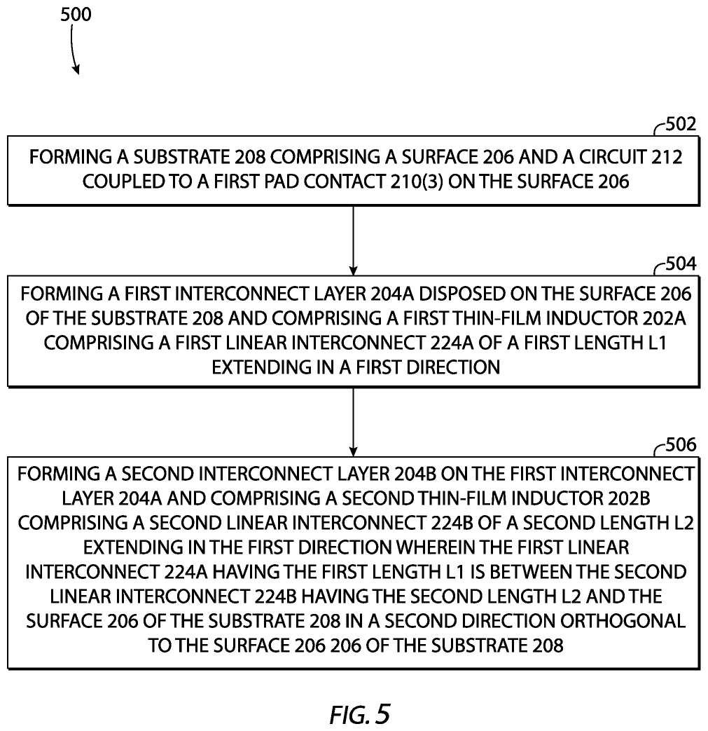

Fabrication processes can be employed to fabricate an IC including a first thin-film inductor and a second thin-film inductor stacked in a direction orthogonal to a surface of a substrate, including but not limited to the ICs 200, 303, and 401 of FIGS. 2A-2D, 3, and 4, respectively. In this regard, FIG. 5 is a flowchart illustrating an exemplary fabrication process 500 of fabricating the IC 200 including a first thin-film inductor 202A and a second thin-film inductor 202B stacked in a direction (Z-axis direction) orthogonal to a surface 206 of a substrate 208. The fabrication process 500 in FIG. 5 is discussed with regard to the IC 200 in FIGS. 2A-2D, but note that the fabrication process 500 in FIG. 5 is not limited to fabricating the IC 200 as illustrated in FIGS. 2A-2D.

In this regard, an exemplary step in the method 500 of fabricating the IC 200 includes forming a substrate 208 comprising a surface 206 and a circuit 212 coupled to a first pad contact 210(3) on the surface 206(block 502). The method includes forming a first interconnect layer 204A disposed on the surface 206 of the substrate 208 and comprising a first thin-film inductor 202A comprising a first linear interconnect 224A of a first length L1 extending in a first direction (block 504) and forming a second interconnect layer 204B on the first interconnect layer 204A and comprising a second thin-film inductor 202B comprising a second linear interconnect 224B of a second length L2 extending in the first direction wherein the first linear interconnect 224A having the first length L1 is between the second linear interconnect 224B having the second length L2 and the surface 206 of the substrate 208 in a second direction orthogonal to the surface 206 of the substrate 208 (block 506).

Other fabrication processes can also be employed to fabricate an IC including a first thin-film inductor and a second thin-film inductor stacked in a direction orthogonal to a surface of a substrate including but not limited to the ICs 200, 303, and 401 in FIGS. 2A-2D, 3, and 4.

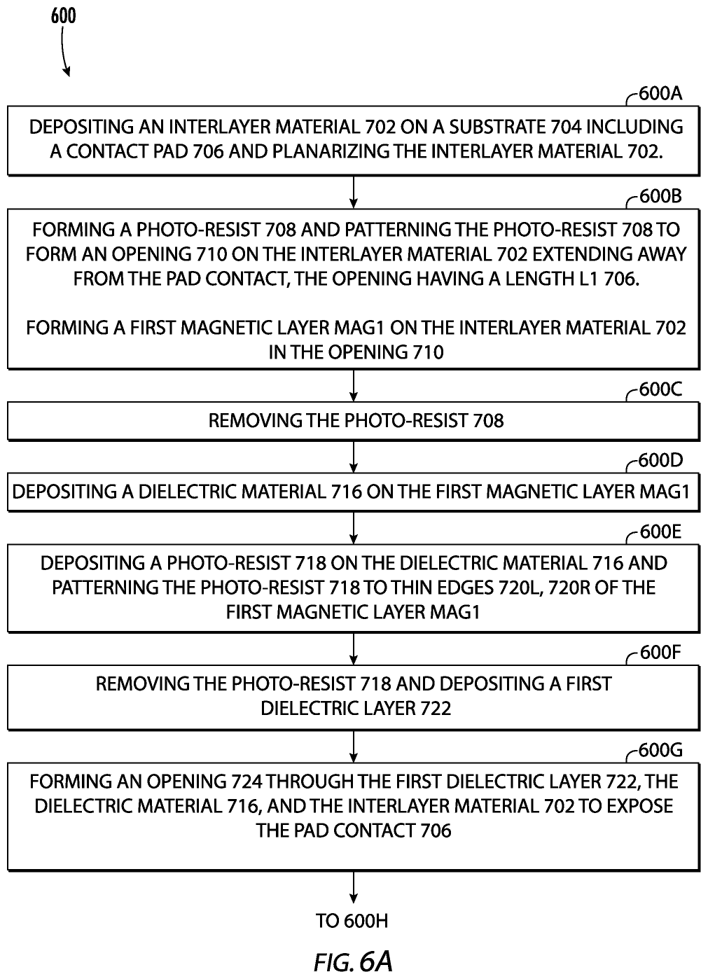

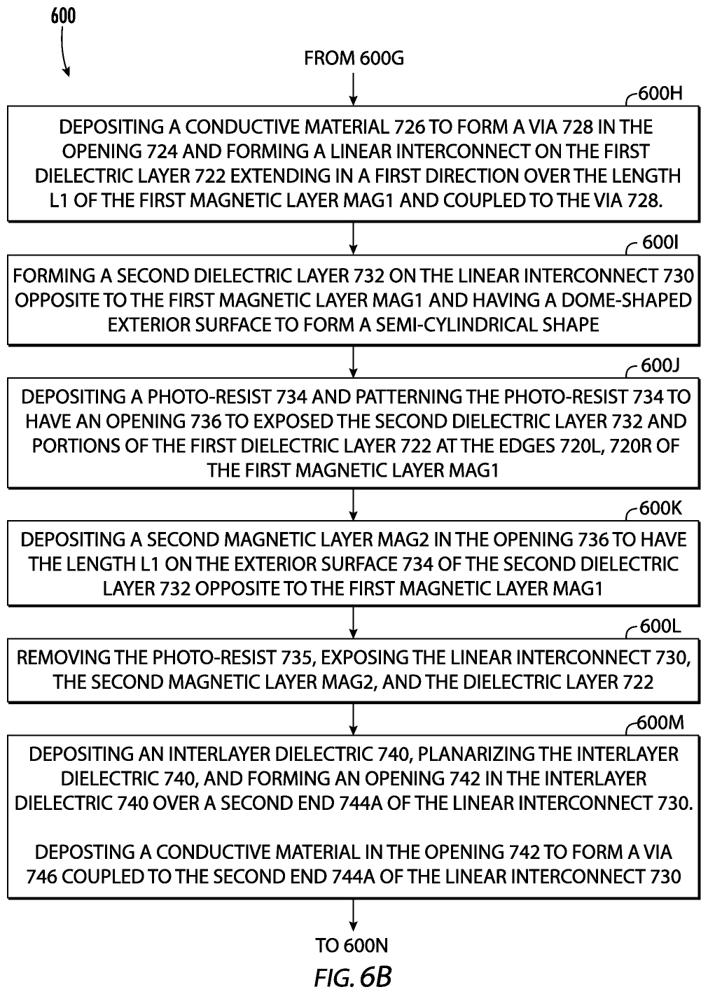

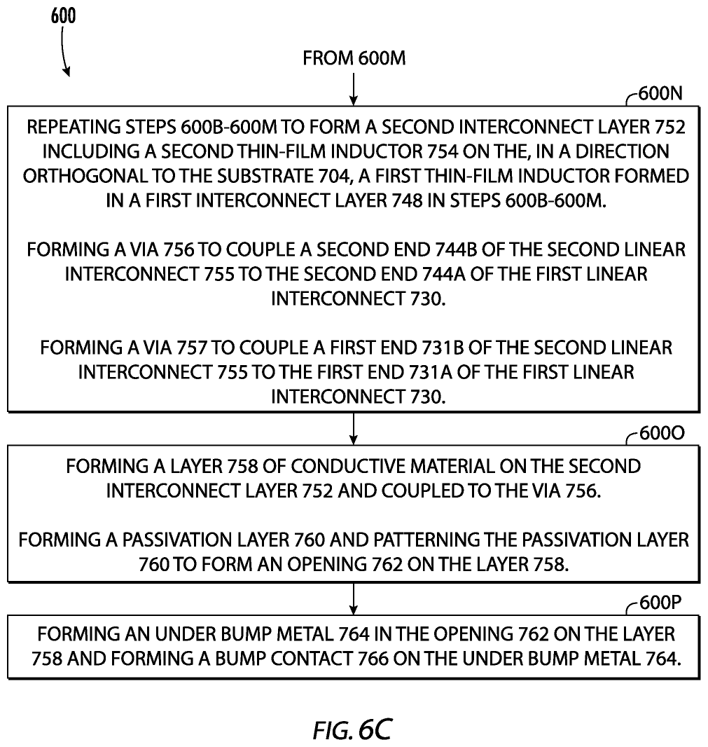

In this regard, FIGS. 6A-6C are a flowchart illustrating another exemplary fabrication process 600 of fabricating an IC including a first thin-film inductor and a second thin-film inductor stacked in a direction orthogonal to a surface of a substrate including but not limited to the ICs 200, 303, and 401 in FIGS. 2A-2D, 3, and 4. FIGS. 7A-1 to 7P-2 are exemplary fabrication stages 700A-700P during fabrication of the IC including a first thin-film inductor and a second thin-film inductor stacked in a direction orthogonal to a surface of a substrate according to the fabrication process 600 in FIGS. 6A-6C. The fabrication process 600 in FIGS. 6A-6C will now be discussed in conjunction with the exemplary fabrication stages 700A-700P in FIGS. 7A-1 to 7P-2 using the IC 200 in FIGS. 2A-2D as an example. However, note that the fabrication process 600 in FIGS. 6A-6C represented by the fabrication stages 700A-700P in FIGS. 7A-1 to 7P-2 could also be applicable to fabricate the ICs 303 and 401 in FIGS. 3 and 4 as well.

In this regard, as shown in the fabrication stage 700A in FIGS. 7A-1 and 7A-2, a first step 600A in the fabrication process 600 is to deposit an interlayer material 702, such as a dielectric material, on a substrate 704 such as a die including a pad contact 706. The substrate 704 includes circuits (not shown) which may be, for example, logic circuits or power management circuits. An insulation layer 707 on the substrate 704 includes an opening over the pad contact 706. The interlayer material 702 is deposited on the pad contact 706, which may be electrically coupled to the circuits on the substrate 704. The interlayer material 702 may be planarized to a desired thickness.

In the fabrication stage 700B in FIGS. 7B-1 and 7B-2, a next step 600B in the fabrication process 600 is to form a photo-resist 708 that is patterned to form an opening 710 on the interlayer material 702 and extends in a first direction (X-axis direction) from the pad contact 706. A length L1 of the opening 710 corresponds to a length L1 of a desired thin-film inductor. A first magnetic layer MAG1 of a magnetic material 714 is formed on the photo-resist 708 and on the interlayer material 702 in the opening 710. The magnetic material 714 may be, for example, a composite of cobalt zirconium and tantalum (CZT).

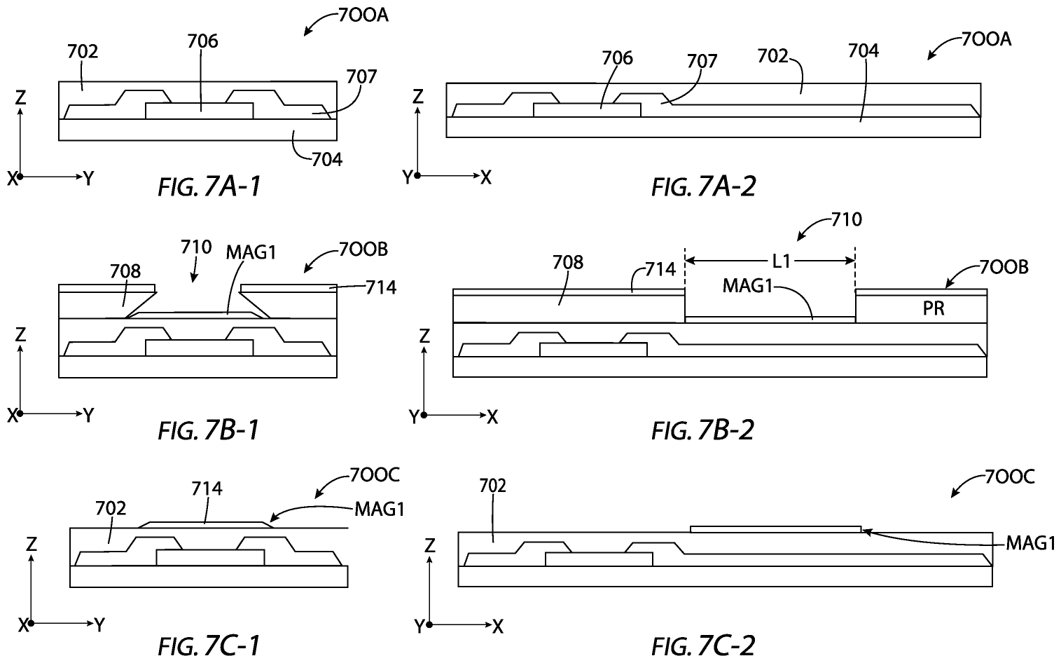

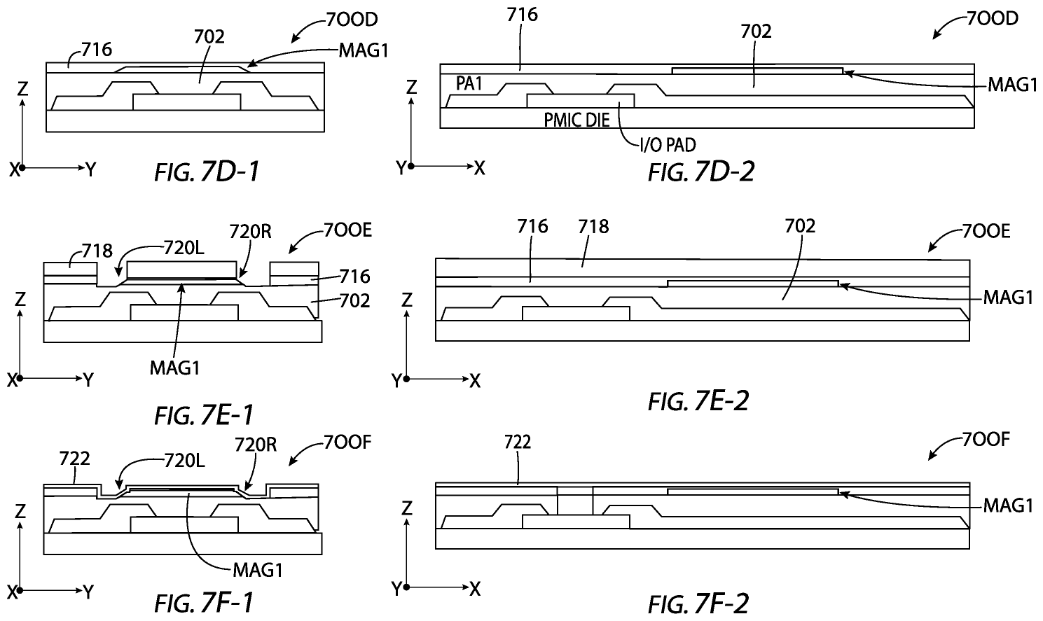

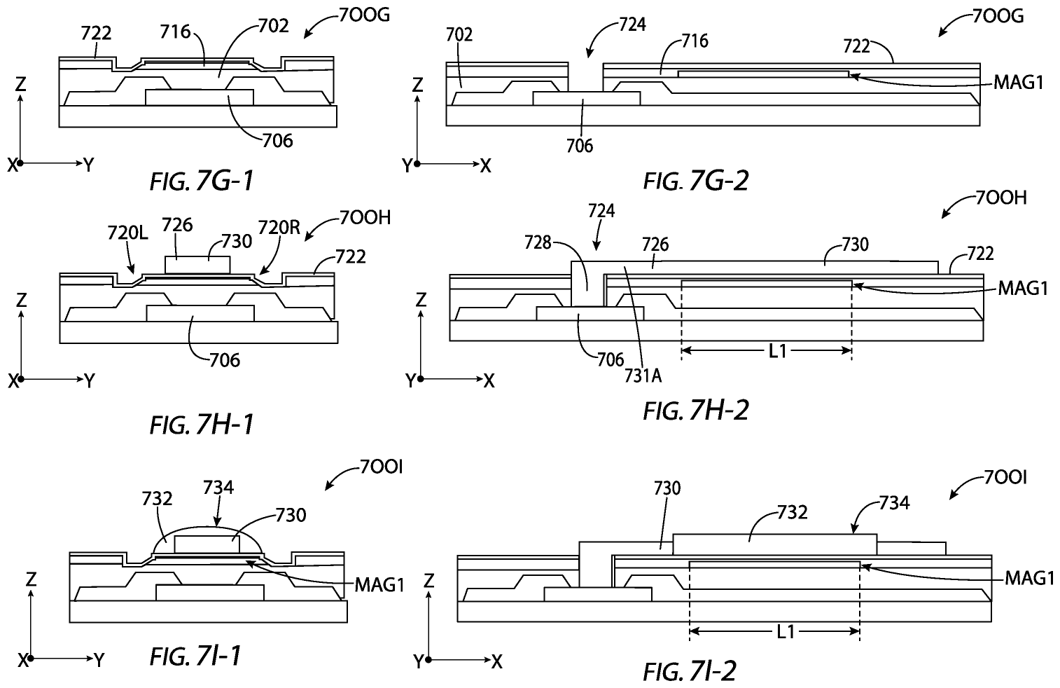

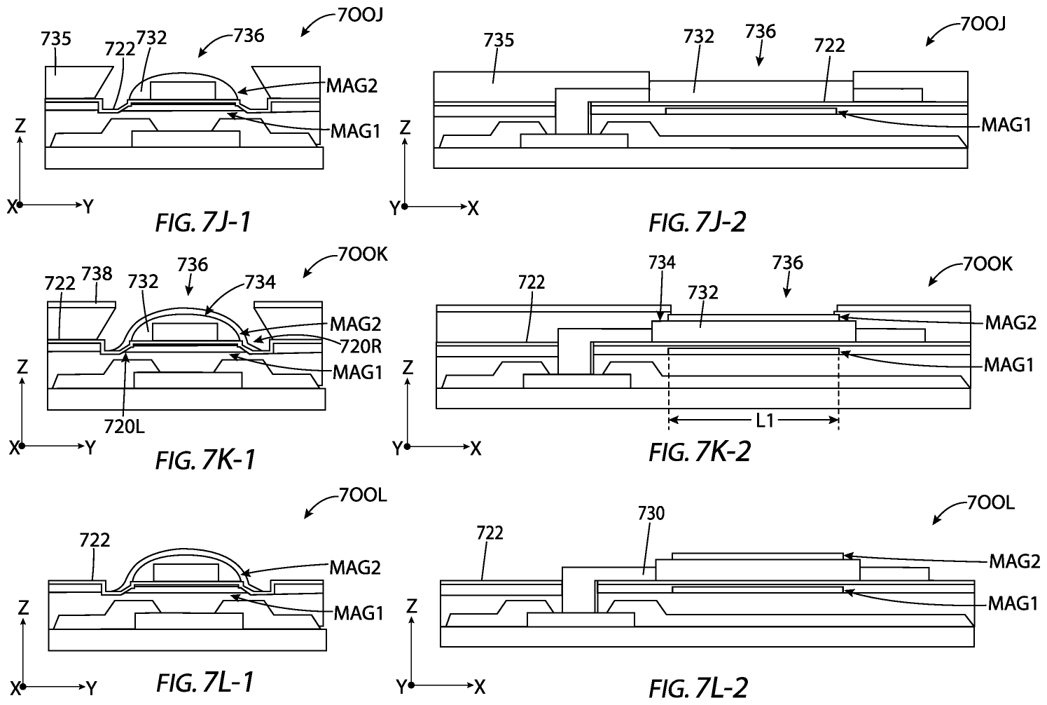

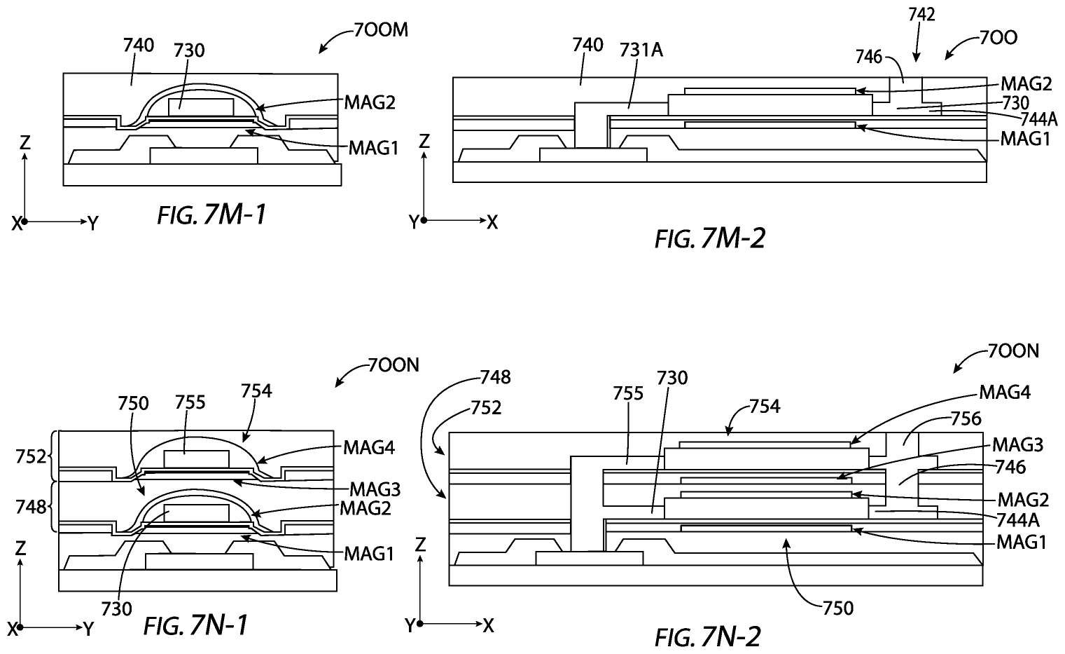

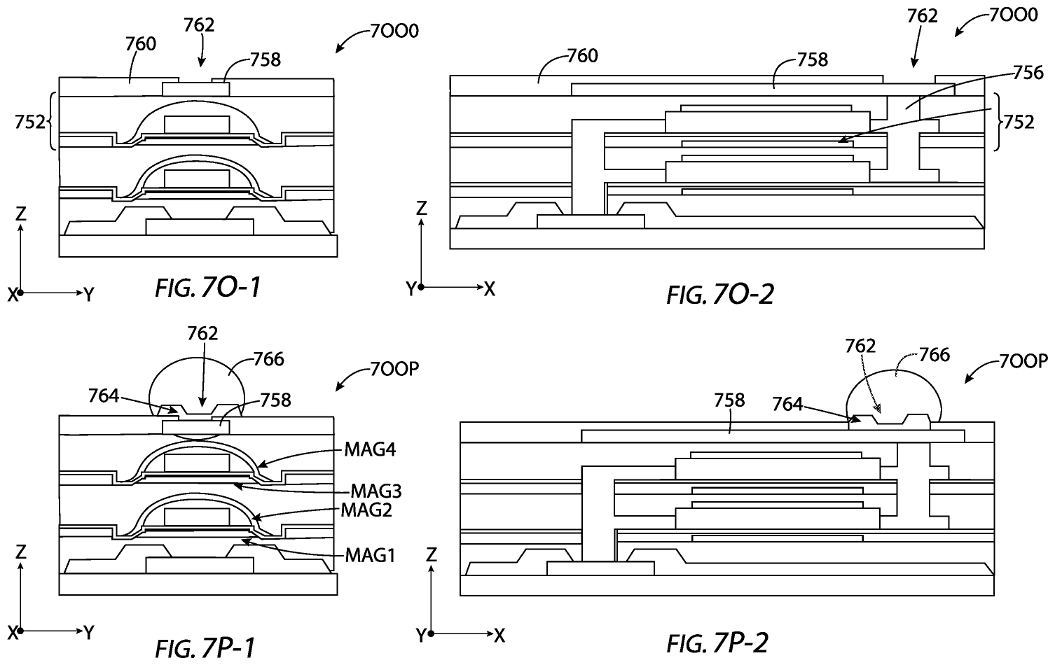

In the fabrication stage 700C in FIGS. 7C-1 and 7C-2, a next step 600C in the fabrication process 600 is to remove the photo-resist 708 (See FIG. 7B-1) and portions of the magnetic material 714 formed thereon, leaving the first magnetic layer MAG1 on the interlayer material 702. The first magnetic layer MAG1 may be a planar layer.

In the fabrication stage 700D in FIGS. 7D-1 and 7D-2, a next step 600D in the fabrication process 600 is to deposit a dielectric material 716 on the first magnetic layer MAG1 and on the interlayer material 702.

In the fabrication stage 700E in FIGS. 7E-1 and 7E-2, a next step 600E in the fabrication process 600 is to deposit a photo-resist 718 on the dielectric material 716 and pattern the photo-resist 718 using an etching process, such as a deep reactive ion etch (DRIE). This process gradually thins edges 720L and 720R of the first magnetic layer MAG1, where the edges 720L, 720R extend in the first direction, and exposes portions of the interlayer material 702.

In the fabrication stage 700F in FIGS. 7F-1 and 7F-2, a next step 600F in the fabrication process 600 is to remove the photo-resist 718 shown in FIG. 7E-1 and deposit a first dielectric layer 722. The first dielectric layer 722 may be a thin layer employed to separate the edges 720L, 720R of the first magnetic layer MAG1 from another magnetic layer, as follows.

In the fabrication stage 700G in FIGS. 7G-1 and 7G-2, a next step 600G in the fabrication process 600 is to, as shown more clearly in FIG. 7G-2, form an opening 724, such as by DRIE, through the first dielectric layer 722, the dielectric material 716, and the interlayer material 702 to expose the pad contact 706.

In the fabrication stage 700H in FIGS. 7H-1 and 7H-2, a next step 600H in the fabrication process 600 is to deposit a conductive material 726, such as copper, to form a via 728 in the opening 724. The conductive material 726 electrically couples to the pad contact 706 and extends orthogonal to the pad contact 706. The conductive material 726 is also patterned to form a linear interconnect 730 on the first dielectric layer 722 extending in the first direction over the length L1 of the first magnetic layer MAG1. A first end 731A of the linear interconnect 730 is coupled to the via 728. The linear interconnect 730 may be centered in the Y-axis direction between the edges 720L and 720R.

In the fabrication stage 7001 in FIGS. 71-1 and 71-2, a next step 600I in the fabrication process 600 is to employ photolithographic patterning to form a second dielectric layer 732 on the linear interconnect 730, opposite to the first magnetic layer MAG1, and having a dome-shaped cross-section in the X-axis direction. The second dielectric layer 732 extends in the first direction over at least the first length L1 of the first magnetic layer MAG1. The dome-shaped cross-section causes the second dielectric layer 732 to have an exterior surface 734 that approximates a semi-cylindrical shape.

In the fabrication stage 700J in FIGS. 7J-1 and 7J-2, a next step 600J in the fabrication process 600 is to deposit a photo-resist 735 and pattern the photo-resist 735 to have an opening 736 to expose the second dielectric layer and portions of the first dielectric layer 722 at the edges 720L, 720R of the first magnetic layer MAG1.

In the fabrication stage 700K in FIGS. 7K-1 and 7K-2, a next step 600K in the fabrication process 600 is to deposit a second magnetic layer MAG2. In the opening 736, the second magnetic layer MAG2 is formed to have the first length L1 on the semi-cylindrical (e.g., dome shaped) exterior surface 734 of the second dielectric layer 732 opposite to the first magnetic layer MAG1. The second magnetic layer MAG2 is also formed on the first dielectric layer 722 on the edges 720L, 720R of the first magnetic layer MAG1. Thus, the second magnetic layer MAG2 is separated from the edges 720L, 720R of the first magnetic layer MAG1 by the first dielectric layer 722.

In the fabrication stage 700L in FIGS. 7L-1 and 7L-2, a next step 600L in the fabrication process 600 is to remove the photo-resist 735, exposing the linear interconnect 730, the second magnetic layer MAG2, and the remainder of the first dielectric layer 722.

In the fabrication stage 700M in FIGS. 7M-1 and 7M-2, a next step 600M in the fabrication process 600 is to deposit an interlayer dielectric 740, planarize the interlayer dielectric 740, and form an opening 742 in the interlayer dielectric 740 over a second end 744A of the linear interconnect 730. The second end 744A and the first end 731A are at opposite ends of the second magnetic layer MAG2 in the first direction. Step 600M also includes depositing a conductive material in the opening 742 to form a via 746 coupled to the second end 744A of the linear interconnect 730.

In this manner steps 600B-600M have formed a first interconnect layer 748 including a first thin-film inductor 750 including the first and second magnetic layers MAG1, MAG2 on opposite sides of the linear interconnect 730. In the fabrication stage 700N in FIGS. 7N-1 and 7N-2, in a step 600N in the fabrication process 600, steps 600B-600M are repeated to form a second interconnect layer 752 including a second thin-film inductor 754 stacked on, in a direction orthogonal to the substrate 704 (e.g., the Z-axis direction), the first thin-film inductor 750. The second thin-film inductor 754 includes first and second magnetic layers MAG3, MAG4 on opposite sides of a linear interconnect 755. The second interconnect layer 752 includes a via 756 to couple the second end 744B of the second linear interconnect 755 to the second end 744A of the linear interconnect 730. Step 600N also includes forming a via 757 to couple a first end 731B of the second linear interconnect 755 to the first end 731A of the first linear interconnect 730.

In the fabrication stage 700O in FIGS. 70-1 and 70-2, a next step 600O in the fabrication process 600 is to form a layer 758 of conductive material (e.g., metal) on the second interconnect layer 752 and coupled to the via 756 in the second interconnect layer 752. The step 600O also includes forming a passivation layer 760 and patterning the passivation layer 760 to form an opening 762 on the layer 758.

In the fabrication stage 700P in FIGS. 7P-1 and 7P-2, a next step 600P in the fabrication process 600 is to form an under-bump metal 764 on the opening 762 and on the layer 758. Forming a bump contact 766 on the under-bump metal 764.

Electronic devices according to any aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, laptop computer, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

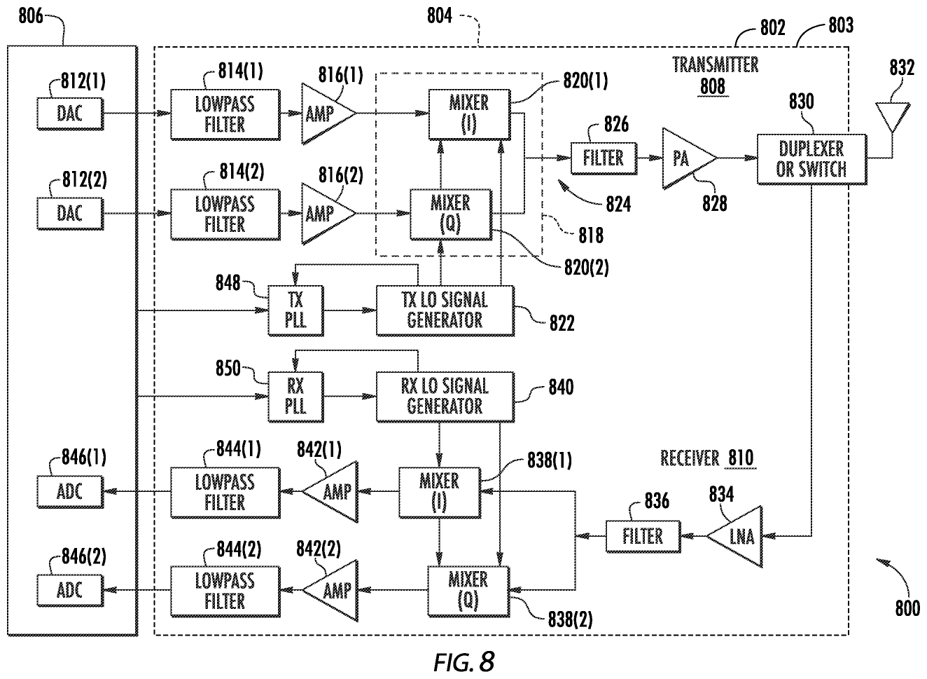

In this regard, FIG. 8 illustrates a block diagram of an exemplary wireless communications device 800 that includes radio frequency (RF) components formed from one or more ICs 802, wherein any of the ICs 802 can include a first thin-film inductor and a second thin-film inductor stacked in a direction orthogonal to a surface of a substrate to reduce noise and/or surges in input signals as shown in any of FIGS. 2A-4. The wireless communications device 800 may include or be provided as examples in any of the above-referenced devices. As shown in FIG. 8, the wireless communications device 800 includes a transceiver 804 and a data processor 806. The data processor 806 may include a memory to store data and program codes. The transceiver 804 includes a transmitter 808 and a receiver 810, which support bi-directional communications. In general, the wireless communications device 800 may include any number of transmitters 808 and/or receivers 810 for any number of communication systems and frequency bands. All or a portion of the transceiver 804 may be implemented on one or more analog ICs, RF ICs (RFICs), mixed-signal ICs, etc.

The transmitter 808 or the receiver 810 may be implemented with a super-heterodyne or direct-conversion architecture. In the super-heterodyne architecture, a signal is frequency-converted between RF and baseband in multiple stages, e.g., from RF to an intermediate frequency (IF) in one stage and then from IF to baseband in another stage. In the direct-conversion architecture, a signal is frequency-converted between RF and baseband in one stage. The super-heterodyne and direct-conversion architectures may use different circuit blocks and/or have different requirements. In the wireless communications device 800 in FIG. 8, the transmitter 808 and the receiver 810 are implemented with the direct-conversion architecture.

In the transmit path, the data processor 806 processes data to be transmitted and provides I and Q analog output signals to the transmitter 808. In the exemplary wireless communications device 800, the data processor 806 includes digital-to-analog converters (DACs) 812(1), 812(2) for converting digital signals generated by the data processor 806 into I and Q analog output signals, e.g., I and Q output currents, for further processing.

Within the transmitter 808, lowpass filters 814(1), 814(2) filter the I and Q analog output signals, respectively, to remove undesired signals caused by the prior digital-to-analog conversion. Amplifiers (AMPs) 816(1), 816(2) amplify the signals from the lowpass filters 814(1), 814(2), respectively, and provide I and Q baseband signals. An upconverter 818 upconverts the I and Q baseband signals with I and Q transmit (TX) local oscillator (LO) signals from a TX LO signal generator 822 through mixers 820(1), 820(2) to provide an upconverted signal 824. A filter 826 filters the upconverted signal 824 to remove undesired signals caused by the frequency upconversion and noise in a receive frequency band. A power amplifier (PA) 828 amplifies the upconverted signal 824 from the filter 826 to obtain the desired output power level and provides a transmit RF signal. The transmit RF signal is routed through a duplexer or switch 830 and transmitted via an antenna 832.

In the receive path, the antenna 832 receives signals transmitted by base stations and provides a received RF signal, which is routed through the duplexer or switch 830 and provided to a low noise amplifier (LNA) 834. The duplexer or switch 830 is designed to operate with a specific receive (RX)-to-TX duplexer frequency separation, such that RX signals are isolated from TX signals. The received RF signal is amplified by the LNA 834 and filtered by a filter 836 to obtain a desired RF input signal. Downconversion mixers 838(1), 838(2) mix the output of the filter 836 with I and Q RX LO signals (i.e., LO_I and LO_Q) from an RX LO signal generator 840 to generate I and Q baseband signals. The I and Q baseband signals are amplified by AMPs 842(1), 842(2) and further filtered by lowpass filters 844(1), 844(2) to obtain I and Q analog input signals, which are provided to the data processor 806. In this example, the data processor 806 includes analog-to-digital converters (ADCs) 846(1), 846(2) for converting the analog input signals into digital signals to be further processed by the data processor 806.

In the wireless communications device 800 of FIG. 8, the TX LO signal generator 822 generates the I and Q TX LO signals used for frequency upconversion, while the RX LO signal generator 840 generates the I and Q RX LO signals used for frequency downconversion. Each LO signal is a periodic signal with a particular fundamental frequency. A TX phase-locked loop (PLL) circuit 848 receives timing information from the data processor 806 and generates a control signal used to adjust the frequency and/or phase of the TX LO signals from the TX LO signal generator 822. Similarly, an RX PLL circuit 850 receives timing information from the data processor 806 and generates a control signal used to adjust the frequency and/or phase of the RX LO signals from the RX LO signal generator 840.

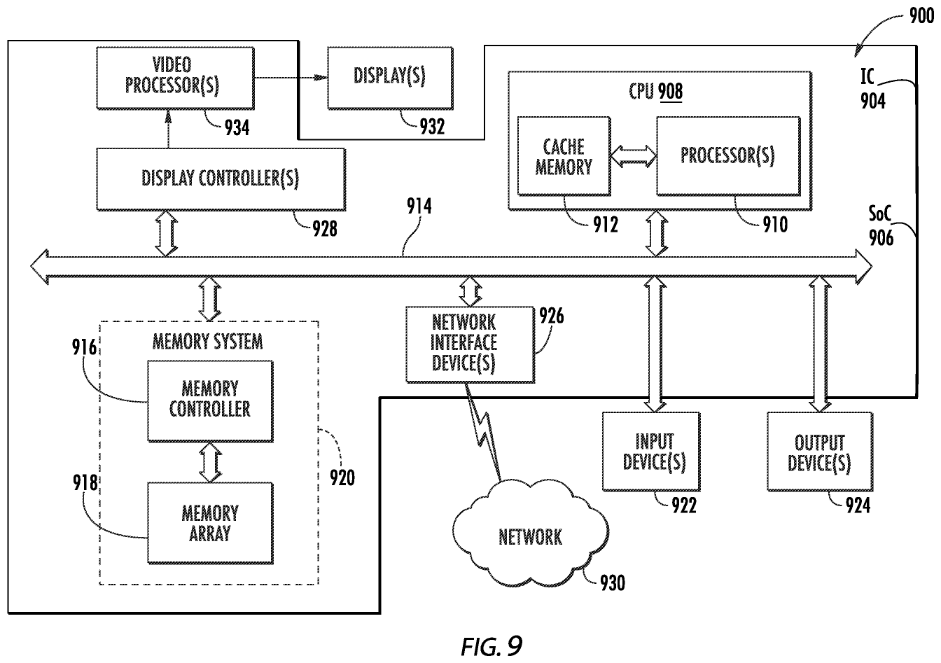

FIG. 9 illustrates a block diagram of an example of a processor-based system 900 that can employ integrated circuits, including an integrated circuit (IC) 904 comprising a first thin-film inductor and a second thin-film inductor stacked in a direction orthogonal to a surface of a substrate to reduce noise and/or surges in input signals as shown in any of FIGS. 2A-4. In this example, the processor-based system 900 includes one or more central processor units (CPUs) 908, which may also be referred to as CPU or processor cores, each including one or more processors 910. The CPU(s) 908 may have cache memory 912 coupled to the processor(s) 910 for rapid access to temporarily stored data. The CPU(s) 908 is coupled to a system bus 914 and can intercouple master and slave devices included in the processor-based system 900. As is well known, the CPU(s) 908 communicates with these other devices by exchanging address, control, and data information over the system bus 914. For example, the CPU(s) 908 can communicate bus transaction requests to a memory controller 916 as an example of a slave device. Although not illustrated in FIG. 9, multiple system buses 914 could be provided wherein each system bus 914 constitutes a different fabric.

Other master and slave devices can be connected to the system bus 914. As illustrated in FIG. 9, these devices can include a memory system 920 that includes the memory controller 916 and one or more memory arrays 918, one or more input devices 922, one or more output devices 924, one or more network interface devices 926, and one or more display controllers 928, as examples. The input device(s) 922 can include any type of input device, including, but not limited to, input keys, switches, voice processors, etc. The output device(s) 924 can include any type of output device, including, but not limited to, audio, video, other visual indicators, etc. The network interface device(s) 926 can be any device configured to allow an exchange of data to and from a network 930. The network 930 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 926 can be configured to support any type of communications protocol desired.

The CPU(s) 908 may also be configured to access the display controller(s) 928 over the system bus 914 to control information sent to one or more displays 932. The display controller(s) 928 sends information to the display(s) 932 to be displayed via one or more video processors 934, which process the information to be displayed into a format suitable for the display(s) 932. The display(s) 932 can include any type of display, including, but not limited to, a cathode ray tube (CRT), a liquid crystal display (LCD), a plasma display, or a light-emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. As examples, the devices and components described herein may be employed in any circuit, hardware component, integrated circuit (IC), or IC chip. Memory disclosed herein may be any type and size of memory and may be configured to store any desired information. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. Alternatively, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using various technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses:
1. An integrated circuit (IC) comprising:
   a substrate comprising a surface and a circuit coupled to a first pad contact on the surface;
   a first interconnect layer disposed on the surface of the substrate and comprising a first thin-film inductor comprising a first linear interconnect of a first length extending in a first direction; and
   a second interconnect layer disposed on the first interconnect layer and comprising a second thin-film inductor comprising a second linear interconnect of a second length extending in the first direction;
   wherein the first linear interconnect having the first length is between the second linear interconnect having the second length and the surface of the substrate in a second direction orthogonal to the surface of the substrate.
2. The IC of clause 1, wherein the first thin-film inductor is coupled in series with the second thin-film inductor.
3. The IC of clause 1, wherein the first thin-film inductor is coupled in parallel with the second thin-film inductor.
4. The IC of clause 1, wherein the first thin-film inductor is electrically isolated from the second thin-film inductor.
5. The IC of any of clause 1 to clause 4, the first thin-film inductor further comprising:
   a first terminal comprising a first end of the first length of the first linear interconnect;
   a second terminal comprising a second end of the first length of the first linear interconnect;
   a first layer of magnetic material disposed on a first side of the first length of the first linear interconnect; and
   a second layer of magnetic material disposed on a second side opposite to the first side of the second length of the second linear interconnect.
6. The IC of any of clause 1 to clause 5, wherein:
   the first layer of magnetic material comprises a planar layer;
   the second layer of magnetic material comprises a semi-cylindrical shape;
   an axis of the semi-cylindrical shape extends in the first direction; and
   the first layer of magnetic material is electrically isolated from the second layer of magnetic material.
7. The IC of any of clause 1 to clause 6, wherein the first linear interconnect is the only linear interconnect between the second layer of magnetic material and the first layer of magnetic material.
8. The IC of clause 6 or clause 7, the first thin-film inductor further comprising:
   a first dielectric layer disposed between the first linear interconnect and the first layer of magnetic material; and
   a second dielectric layer disposed in the semi-cylindrical shape between the first linear interconnect and the second layer of magnetic material.
9. The IC of any of clause 5 to clause 8, the second thin-film inductor further comprising:
   a third terminal coupled to a first end of the second length of the second linear interconnect;
   a fourth terminal coupled to a second end of the second length of the second linear interconnect;
   a third layer of magnetic material disposed on a first side of the second linear interconnect between the second linear interconnect and the second layer of the magnetic material of the first thin-film inductor; and
   a fourth layer of the magnetic material disposed on a second side opposite to the first side of the second length of the second linear interconnect.
10. The IC of any of clause 1 to clause 9, further comprising:
   a first vertical interconnect extending in the second direction and coupled to the first pad contact and at least one of the first linear interconnect and the second linear interconnect.
11. The IC of any of clause 1 to clause 3 and clause 5 to clause 10, further comprising:
   a second vertical interconnect extending in the second direction and coupling the first linear interconnect to the second linear interconnect.
12. The IC of clause 11, further comprising:
   a third vertical interconnect extending in the second direction and coupling the first linear interconnect to the second linear interconnect;
   wherein:
   the second vertical interconnect is coupled a first end of the first linear interconnect and the third vertical interconnect is coupled to a second end of the first linear interconnect.
13. The IC of any of clause 1 to clause 12, further comprising:
   a first bump interconnect disposed on the second interconnect layer; and
   a fourth vertical interconnect extending in the second direction and coupled to the first bump interconnect and at least one of the first linear interconnect and the second linear interconnect.
14. The IC of clause 13, further comprising:
   a second bump interconnect disposed on the second interconnect layer, wherein:
      the fourth vertical interconnect couples the first bump interconnect to the first linear interconnect; and
      the second bump interconnect is coupled to the second linear interconnect.
15. The IC of clause 14, further comprising a second pad contact coupled to the second linear interconnect.
16. The IC of clause 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
17. A method of fabricating an integrated circuit (IC), the method comprising:
   forming a substrate comprising a surface and a circuit coupled to a first pad contact on the surface;
   forming a first interconnect layer on the surface of the substrate and comprising a first thin-film inductor comprising a first linear interconnect of a first length extending in a first direction; and
   forming a second interconnect layer disposed on the first interconnect layer and comprising a second thin-film inductor comprising a second linear interconnect of a second length extending in the first direction;
   wherein the first linear interconnect having the first length is between the second linear interconnect having the second length and the surface of the substrate in a second direction orthogonal to the surface of the substrate.
18. The method of clause 17, wherein forming the first interconnect layer comprises:
   forming a first dielectric layer on the surface of the substrate;
   forming a first magnetic layer having the first length in the first direction on the first dielectric layer;
   forming a second dielectric layer on the first magnetic layer;
   forming the first linear interconnect on the second dielectric layer;
   forming a third dielectric layer having a semi-cylindrical shape on the first linear interconnect, the semi-cylindrical shape having an axis extending in the first direction; and
   forming a second magnetic layer having the first length in the first direction on the third dielectric layer.
19. The method of clause 18, wherein forming the second interconnect layer comprises:
   forming a fourth dielectric layer on the second magnetic layer;
   forming a third magnetic layer having the first length in the first direction on the fourth dielectric layer;
   forming a fifth dielectric layer on the third magnetic layer;
   forming the second linear interconnect on the fifth dielectric layer;
   forming a sixth dielectric layer having the semi-cylindrical shape on the second linear interconnect, the semi-cylindrical shape having the axis extending in the first direction; and
   forming a fourth magnetic layer having the first length in the first direction on the sixth dielectric layer.
20. The method of any of clause 17 to clause 19, further comprising:
   forming a first vertical interconnect extending in the second direction to couple the first pad contact to at least one of the first linear interconnect and the second linear interconnect;
   forming a first bump interconnect on the second interconnect layer; and
   forming a second vertical interconnect extending in the second direction to couple the first bump interconnect to at least one of the first linear interconnect and the second linear interconnect.

What is claimed is:

1. An integrated circuit (IC) comprising:
a substrate comprising a surface and a circuit coupled to a first pad contact on the surface;
a first interconnect layer disposed on the surface of the substrate and comprising a first thin-film inductor comprising a first linear interconnect of a first length extending in a first direction; and
a second interconnect layer disposed on the first interconnect layer and comprising a second thin-film inductor comprising a second linear interconnect of a second length extending in the first direction;
wherein the first linear interconnect having the first length is between the second linear interconnect having the second length and the surface of the substrate in a second direction orthogonal to the surface of the substrate.

2. The IC of claim 1, wherein the first thin-film inductor is coupled in series with the second thin-film inductor.

3. The IC of claim 1, wherein the first thin-film inductor is coupled in parallel with the second thin-film inductor.

4. The IC of claim 1, wherein the first thin-film inductor is electrically isolated from the second thin-film inductor.

5. The IC of claim 1, the first thin-film inductor further comprising:
a first terminal comprising a first end of the first length of the first linear interconnect;
a second terminal comprising a second end of the first length of the first linear interconnect;
a first layer of magnetic material disposed on a first side of the first length of the first linear interconnect; and
a second layer of magnetic material disposed on a second side opposite to the first side of the second length of the second linear interconnect.

6. The IC of claim 5, wherein:
the first layer of magnetic material comprises a planar layer;
the second layer of magnetic material comprises a semi-cylindrical shape;
an axis of the semi-cylindrical shape extends in the first direction; and
the first layer of magnetic material is electrically isolated from the second layer of magnetic material.

7. The IC of claim 5, wherein the first linear interconnect is the only linear interconnect between the second layer of magnetic material and the first layer of magnetic material.

8. The IC of claim 6, the first thin-film inductor further comprising:
a first dielectric layer disposed between the first linear interconnect and the first layer of magnetic material; and
a second dielectric layer disposed in the semi-cylindrical shape between the first linear interconnect and the second layer of magnetic material.

9. The IC of claim 5, the second thin-film inductor further comprising:
a third terminal coupled to a first end of the second length of the second linear interconnect;
a fourth terminal coupled to a second end of the second length of the second linear interconnect;
a third layer of magnetic material disposed on a first side of the second linear interconnect between the second linear interconnect and the second layer of magnetic material of the first thin-film inductor; and
a fourth layer of magnetic material disposed on a second side opposite to the first side of the second length of the second linear interconnect.

10. The IC of claim 1, further comprising:
a first vertical interconnect extending in the second direction and coupled to the first pad contact and at least one of the first linear interconnect and the second linear interconnect.

11. The IC of claim 10, further comprising:
a second vertical interconnect extending in the second direction and coupling the first linear interconnect to the second linear interconnect.

12. The IC of claim 11, further comprising:
a third vertical interconnect extending in the second direction and coupling the first linear interconnect to the second linear interconnect;
wherein:
the second vertical interconnect is coupled a first end of the first linear interconnect and the third vertical interconnect is coupled to a second end of the first linear interconnect.

13. The IC of claim 1, further comprising:
a first bump interconnect disposed on the second interconnect layer; and
a fourth vertical interconnect extending in the second direction and coupled to the first bump interconnect and at least one of the first linear interconnect and the second linear interconnect.

14. The IC of claim 13, further comprising:
a second bump interconnect disposed on the second interconnect layer, wherein:
the fourth vertical interconnect couples the first bump interconnect to the first linear interconnect; and
the second bump interconnect is coupled to the second linear interconnect.

15. The IC of claim 14, further comprising a second pad contact coupled to the second linear interconnect.

16. The IC of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

17. A method of fabricating an integrated circuit (IC), the method comprising:
forming a substrate comprising a surface and a circuit coupled to a first pad contact on the surface;
forming a first interconnect layer on the surface of the substrate and comprising a first thin-film inductor comprising a first linear interconnect of a first length extending in a first direction; and
forming a second interconnect layer disposed on the first interconnect layer and comprising a second thin-film inductor comprising a second linear interconnect of a second length extending in the first direction;
wherein the first linear interconnect having the first length is between the second linear interconnect having the second length and the surface of the substrate in a second direction orthogonal to the surface of the substrate.

18. The method of claim 17, wherein forming the first interconnect layer comprises:
forming a first dielectric layer on the surface of the substrate;
forming a first magnetic layer having the first length in the first direction on the first dielectric layer;
forming a second dielectric layer on the first magnetic layer;
forming the first linear interconnect on the second dielectric layer;
forming a third dielectric layer having a semi-cylindrical shape on the first linear interconnect, the semi-cylindrical shape having an axis extending in the first direction; and
forming a second magnetic layer having the first length in the first direction on the third dielectric layer.

19. The method of claim 18, wherein forming the second interconnect layer comprises:
forming a fourth dielectric layer on the second magnetic layer;
forming a third magnetic layer having the first length in the first direction on the fourth dielectric layer;
forming a fifth dielectric layer on the third magnetic layer;
forming the second linear interconnect on the fifth dielectric layer;
forming a sixth dielectric layer having the semi-cylindrical shape on the second linear interconnect, the semi-cylindrical shape having the axis extending in the first direction; and
forming a fourth magnetic layer having the first length in the first direction on the sixth dielectric layer.

20. The method of claim 17, further comprising:
forming a first vertical interconnect extending in the second direction to couple the first pad contact to at least one of the first linear interconnect and the second linear interconnect;
forming a first bump interconnect on the second interconnect layer; and
forming a second vertical interconnect extending in the second direction to couple the first bump interconnect to at least one of the first linear interconnect and the second linear interconnect.
